(19) United States
(12) Patent Application Publication
(10) Pub. No.: US 2014/0175562 A1
(43) Pub. Date: Jun. 26, 2014

(54) SPACER DIVOT SEALING METHOD AND SEMICONDUCTOR DEVICE INCORPORATING SAME

(71) Applicant: GLOBALFOUNDRIES, INC., Grand Cayman (KY)

(72) Inventors: Haiting Wang, Clifton Park, NY (US); Huang Liu, Mechanicville, NY (US); Yong Meng Lee, Mechanicville, NY (US); Songkram Srivathanakul, Saratoga Springs, NY (US)

(73) Assignee: GLOBALFOUNDRIES, INC., Grand Cayman (KY)

(21) Appl. No.: 13/727,218

(22) Filed: Dec. 26, 2012

(51) Int. Cl. H01L 21/28; H01L 29/423

(52) U.S. Cl. CPC H01L 21/28; H01L 29/4232
USPC 257/401; 438/595

(57) ABSTRACT

A semiconductor structure in fabrication includes a NFET and a PFET. Spacers adjacent gate structures of the NFET and PFET have undesired divots that can lead to substrate damage from chemicals used in a subsequent etch. The fabrication also leaves hard masks over the gate structures with non-uniform height. The divots are filled with material resistant to the chemicals used in the etch. Excess filler is removed, and uniform height is restored. Further fabrication may then proceed.

### BACKGROUND OF THE INVENTION

1. Technical Field

The present invention generally relates to semiconductor devices and methods of fabricating the same. More particularly, the present invention relates to fabricating of a semiconductor gate structure with uniform gate heights and preventing void formation in spacers used along with the gate structures in semiconductor devices.

2. Background Information

Certain semiconductor fabrication processes use sidewall spacers alongside other structures (e.g., transistor gates) to isolate and protect other elements, for example, protecting gate stacks from raised source and drain contacts. During other subsequent processes performed in semiconductor fabrication, the gate structure along with the sidewall spacers are exposed to liquid chemistries, such as solvents and/or aqueous solutions to remove the solvable materials. For example, a gate structure including a resist protect oxide may be formed over the gate structures and the spacers, to protect the underlying structures during subsequent processing. The resist protect oxide may eventually be etched, typically using a combination of dry and wet etching processes that preferentially attack the oxides.

When the resist protect oxide is etched or removed from the surface of the gate structure using conventional etching processes, spacers may also be attacked and voids or divots may be formed at the corners of the spacer exposing adjacent protective layers (e.g., interlayer dielectric oxide and epitaxial layers). During a subsequent anisotropic reactive ion etching process, the divots may provide a pathway for wet etch chemistries such as ammonium hydroxide used in subsequent processing to attack the exposed portions of the underlying adjacent protective layers. This exposure may lead to eating away of the substrate and subsequent filling thereof with metal, forming a defect in the semiconductor device.

Thus, a need exists for a way to create a semiconductor structure without spacer divots.

### SUMMARY OF THE INVENTION

The shortcomings of the prior art are overcome and additional advantages are provided through the provision, in one aspect, of a method of fabricating a semiconductor structure without spacer divots. The method includes providing a semiconductor structure in fabrication having undesired divots in at least some spacers adjacent transistor gate structures, and filling the divots with a filler material prior to subsequent fabrication that may cause substrate damage due to the undesired spacer divots, the filler material being chosen based on the subsequent fabrication.

In accordance with another aspect, a semiconductor structure is provided that includes a plurality of transistors having a plurality of gate structures, and a plurality of spacers adjacent the plurality of gate structures, the plurality of spacers including at least some spacers having a filler material filling a plurality of divots in at least some spacers, and the filler material being resistant to one or more materials used in a subsequent fabrication process.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of an intermediate structure of a semiconductor device in fabrication, the intermediate structure including transistors and gate structures.

FIG. 2 depicts the intermediate structure of FIG. 1 after etching of an interlayer dielectric therein, in accordance with one or more aspects of the present invention.

FIG. 3 depicts the intermediate structure of FIG. 2 after undesired divot formation in spacers adjacent transistor gates therein, in accordance with one or more aspects of the present invention.

FIG. 4 depicts the intermediate structure of FIG. 3 after deposition of filler material to fill the divots, in accordance with one or more aspects of the present invention.

FIG. 5 depicts the resultant structure obtained after removing excess filler material, resulting in a generally planar surface, in accordance with one or more aspects of the present invention, after which further fabrication may take place.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Reference is made below to the drawings, which are not drawn to scale for ease of understanding, wherein the same reference numbers are used throughout different figures designate the same or similar components.

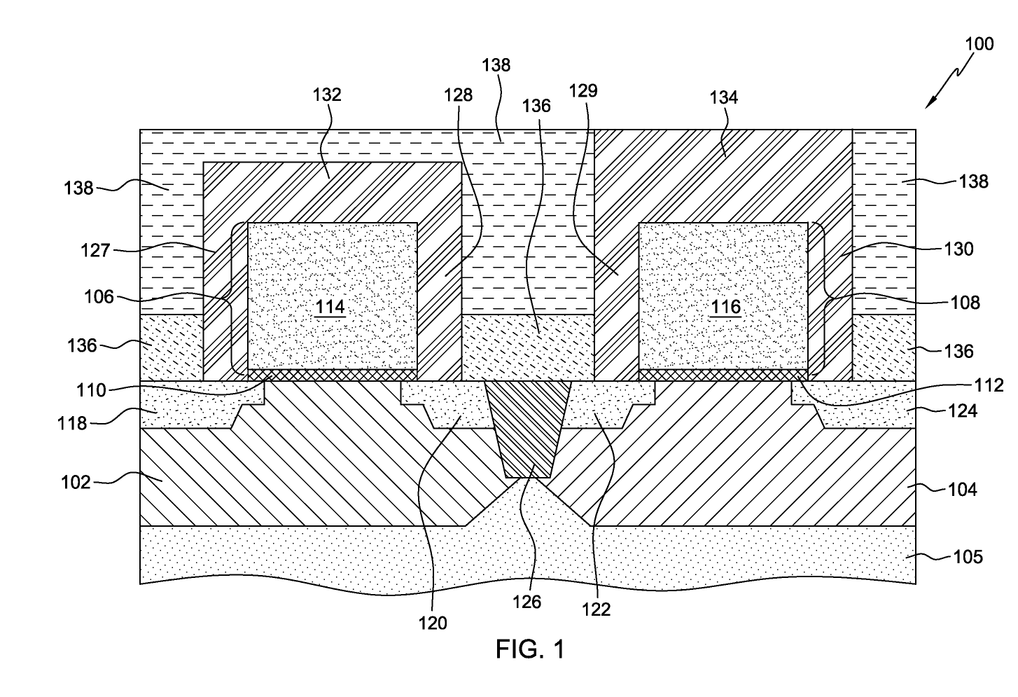

FIG. 1 depicts a cross-section of one example of a CMOS device 100 in fabrication with which the method of the present invention is useful. The CMOS device includes a plurality of transistors, for example, NFET 102 and PFET 104 formed by doping substrate 105, where the substrate may be any silicon-containing substrate including, but not limited to, Si, bulk Si, single crystal Si, polycrystalline Si, SiGe, amorphous Si, Silicon-on-insulator substrates, SiGe-on-insulator substrates and the like. The NFET and PFET include gate stacks 106 and 108, respectively, each including a layer of dielectric material 110 and 112 formed over the NFET and PFET using conventional methods. For example, the dielectric material may include materials such as oxides, nitrides or oxynitrides, for example, silicon dioxide (SiO2), silicon nitride (Si3N4) or high-k dielectric materials, for example, oxides of tantalum (Ta), zirconium (Zr), aluminum (Al) or hafnium (Hf) and the like, formed using conventional deposition processes such as, for example, atomic layer deposition (ALD), chemical vapor deposition (CVD) or physical vapor deposition (PVD). As used herein, the term “high-k dielectric” refers to a dielectric with a dielectric constant k greater than about 3.9 (k=3.9 for SiO2).

Device 100 further includes gate electrodes 114 and 116 formed on dielectric layers 110 and 112. The materials for the gate electrodes may include, for example, polysilicon, amorphous silicon and the like using conventional deposition processes, for example, CVD, plasma-assisted CVD or PVD. At this stage of fabrication, gate electrodes 114 and 116 may be “dummy” electrodes, replaced at a later stage with a different material, for example, metal. The transistors also include raised source/drain extensions 118/120 and 122/124 for the NFET and PFET, respectively. Between extensions 120 and 122 is shallow trench isolation (STI) 126. Adjacent the gate electrodes are spacers 127, 128 and 129, 130, and corresponding hard masks 132 and 134 over the gate electrodes and spacers. The spacer and hard mask material may uniformly include the same material, for example, polysilicon nitride. The spacers and hard masks may be formed by conventional deposition processes, such as, for example, CVD or plasma assisted CVD. The gate stacks and spacers are surrounded by an epitaxial layer 136 which may be deposited using the conventional processes, for example, chemical vapor deposition. The material of the epitaxial layer 136 may include, for example, a homoepitaxial layer of polycrystalline silicon. The epitaxial layer is covered with a layer of interlayer dielectric 138 (e.g., an oxide), using, for example, conventional methods, such as, for example, subatmospheric pressure CVD (SACVD), high density plasma CVD (HDP CVD) or flowable oxide CVD.

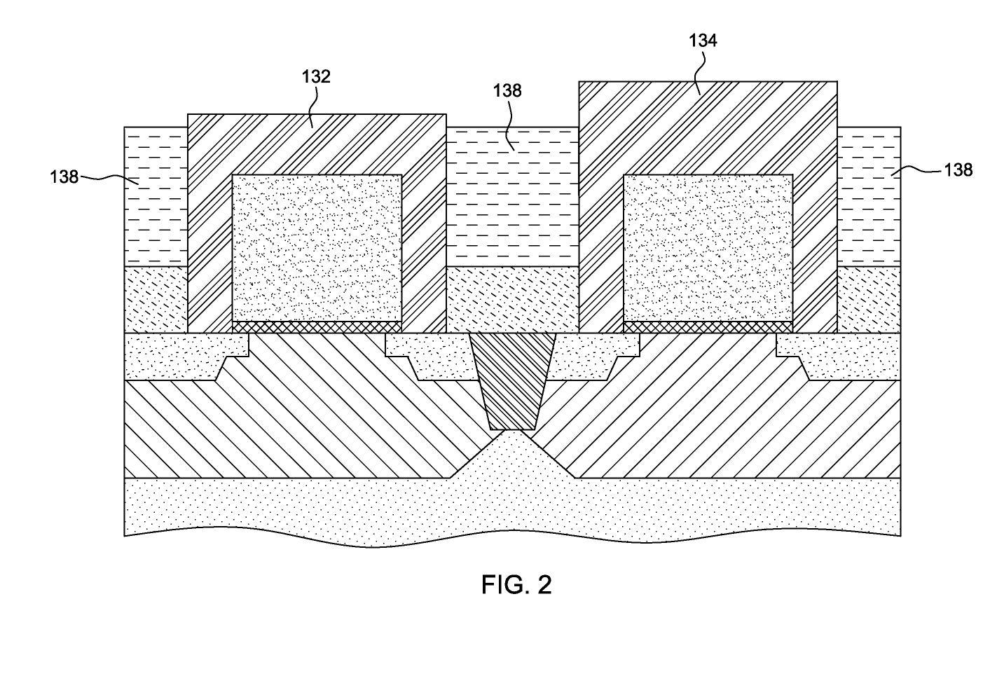

Note that hard mask 134 over the PFET is thicker than hard mask 132 over the NFET due to a prior process. The hard mask height difference is more apparent in FIG. 2, where an isotropic etch-back of interlayer dielectric 138 reveals the hard masks 132 and 134 above the transistors.

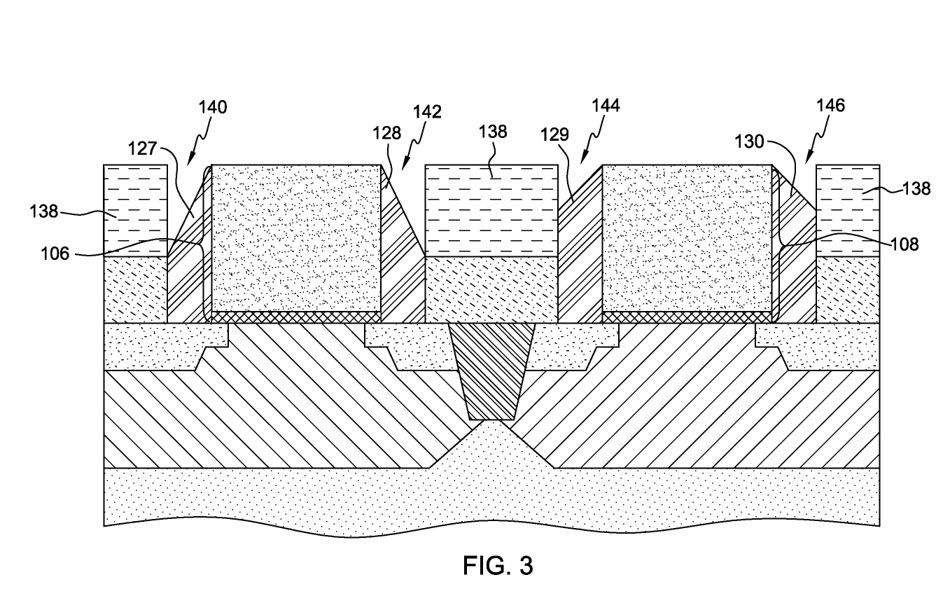

FIG. 3 depicts the device after an etching of the hard masks 132 and 134 revealed in FIG. 2. The etch results in the hard masks being coplanar with interdielectric layer 138, and creates divots in at least some spacers; in this example creating divots 140, 142, 146 and 148 in spacers 127, 128, 129 and 130, respectively. The divots are an unintended consequence of the etch and, if deep enough, expose the underlying epitaxial layer and the substrate underneath to subsequent wet etch chemistries. The etch creating the divots may be, for example, an anisotropic dry etch, accomplished using, for example, reactive ion etching (RIE) using fluorine based chemistry and involving process gases such as tetrafluoromethane (CF₄), trifluoromethane (CHF₃), sulfur hexafluoride (SF₆) and oxygen (O₂). Since, in this example, the spacer and hard mask are uniformly of the same material, the reactive ion etching is also uniform, resulting in deeper divots in spacers 127 and 128 adjacent the NFET gate stack 106 as compared to that of spacers 129 and 130 adjacent the PFET gate stack 108.

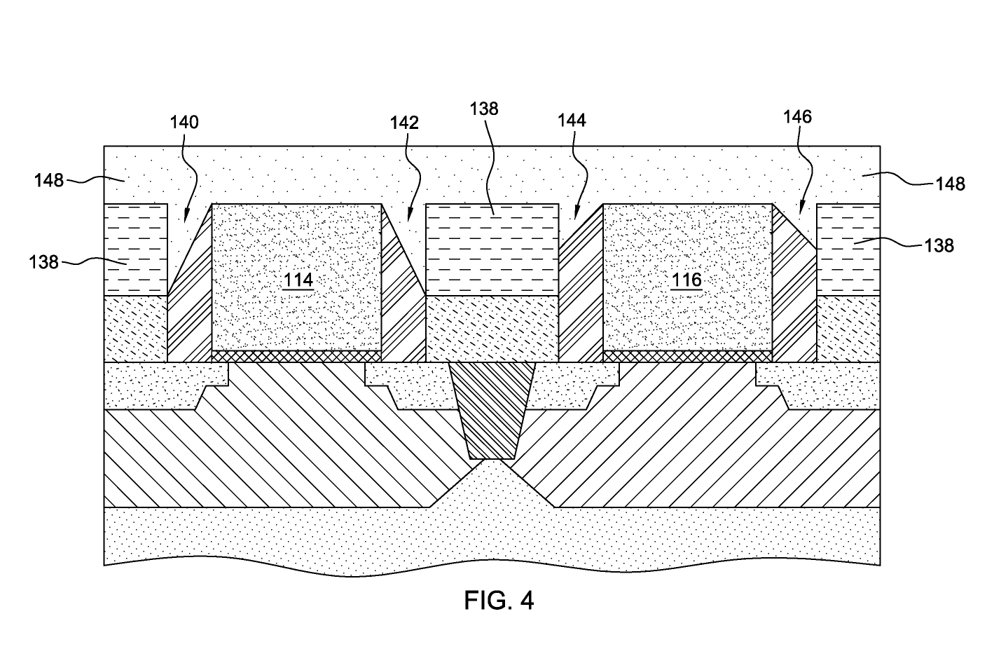

In order to minimize the risk of substrate (transistor) damage, FIG. 4 depicts a conformal deposition of a filler material 148 that fills in divots 140, 142, 144 and 146. Note that there is no longer a height variation between the polycrystalline gate electrodes (114, 116) and interlayer dielectric 138, as their upper surfaces are now approximately coplanar. The filler material 148 may be deposited using conventional deposition processes, such as, for example, atomic layer deposition, and the material includes, for example, a nitride or an oxide chosen to be resistant to any materials and/or gases used in an immediately subsequent process; in this case, an etching process. The thickness of the filler material may be, for example, such as to allow for subsequent planarization.

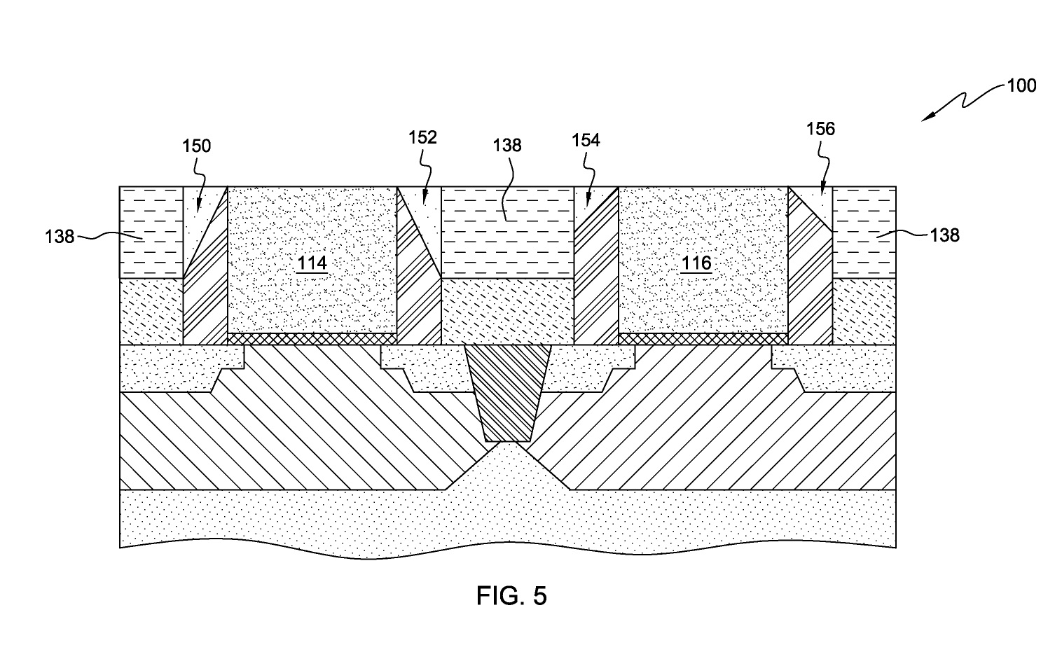

As illustrated in FIG. 5, the excess filler material 148 is selectively removed using a conventional process (e.g., etch back or chemical mechanical polishing) to create a relatively planar surface above the gate electrodes 114 and 116, divot-filled spacers 150, 152, 154 and 156 and interlayer dielectric layer 138. Examples of common etching processes include Reactive ion etching, wet etch and dry etch processes. As the divots are now filled, the desired fabrication process can now proceed.

While several aspects of the present invention have been described and depicted herein, alternative aspects may be effected by those skilled in the art to accomplish the same objectives. For example, aspects of the inventive method may be performed in a different order in some circumstances, and/or additional steps may be performed between the steps described here, without affecting the overall purpose. Accordingly, it is intended by the appended claims to cover all such alternative aspects as fall within the true spirit and scope of the invention.

1. A method, comprising:
providing a semiconductor structure in fabrication having undesired divots in at least some spacers adjacent transistor gate structures; and
filling the divots with a filler material prior to subsequent fabrication that may cause substrate damage due to the undesired spacer divots;
wherein the filler material is chosen based on the subsequent fabrication.

2. The method of claim 1, wherein the filler material is chosen to be resistant to one or more materials used in the subsequent fabrication.

3. The method of claim 2, wherein the subsequent fabrication comprises an etch of material over the transistor gates.

4. The method of claim 3, wherein the material comprises polysilicon, wherein the etch comprises a the wet etch that may expose silicon in the substrate to NH₄OH via epitaxial material adjacent the spacers.

5. The method of claim 1, wherein the filling comprises:
depositing the filler material over the divoted spacers and the transistor gates; and
removing excess filler material.

6. The method of claim 5, further comprising performing the subsequent fabrication after removing the excess filler material.

7. A semiconductor structure, comprising:
a plurality of transistors having a plurality of gate structures; and
a plurality of spacers adjacent the plurality of gate structures;
wherein the plurality of spacers comprise at least some spacers having a filler material filling a plurality of divots in the at least some spacers, and wherein the filler material is resistant to one or more materials used in a subsequent fabrication process.

8. The semiconductor structure of claim 7, wherein the plurality of spacers comprise one of an oxide and a nitride.

9. The semiconductor structure of claim 8, wherein the filler material comprises one of an oxide and a nitride.
